(19) United States
(12) Patent Application Publication
(10) Pub. No.: US 2025/0079425 A1
(43) Pub. Date: Mar. 6, 2025

(54) Semiconductor Package

(71) Applicant: Samsung Electronics Co., Ltd., Suwon-si (KR)

(72) Inventor: Eunsil Kang, Suwon-si (KR)

(21) Appl. No.: 18/820,834

(22) Filed: Aug. 30, 2024

(30) Foreign Application Priority Data
Sep. 4, 2023 (KR) 10-2023-0117221

(51) Int. Cl. H01L 25/18; H01L 23/00; H01L 23/31; H01L 23/538; H01L 23/552; H01L 25/065; H10B 80/00

(52) U.S. Cl. CPC H01L 25/18; H01L 23/3135; H01L 23/5385; H01L 23/552; H01L 23/562; H01L 24/16; H01L 24/17; H01L 24/32; H01L 24/33; H01L 24/73; H01L 25/0657; H01L 2224/16146; H01L 2224/16225; H01L 2224/17181; H01L 2224/32145; H01L 2224/32225; H01L 2224/33181; H01L 2224/73204; H01L 2225/06541; H10B 80/00

(57) ABSTRACT

A semiconductor package includes a first substrate, a first semiconductor chip structure on the first substrate, a second semiconductor chip structure on the first substrate and spaced apart from the first semiconductor chip structure in a first horizontal direction, an underfill material layer filling a space between the first semiconductor chip, the second semiconductor chip structure and the first substrate, and an outermost layer at least partially covering the underfill material layer exposed between the first semiconductor chip, the second semiconductor chip and the first substrate.

### CROSS-REFERENCE TO RELATED APPLICATION

This application is based on and claims priority under 35 USC § 119 to Korean Patent Application No. 10-2023-0117221, filed on Sep. 4, 2023, in the Korean Intellectual Property Office, the disclosure of which is incorporated by reference herein in its entirety.

### BACKGROUND

The inventive concept relates to a semiconductor package, and more particularly, to a semiconductor package including an outermost layer.

Recently, demand for portable devices has rapidly increased in the electronic product market, and as a result, there is a continuous demand for miniaturization and weight reduction of electronic components mounted on electronic products. In order to miniaturize and reduce the weight of electronic components, semiconductor packages mounted on electronic components are required to decrease in volume, process high-capacity data, and minimize defects.

### SUMMARY

The inventive concept provides a semiconductor package having improved reliability.

In addition, the problem to be solved by the inventive concept is not limited to the problems mentioned above, and other problems may be clearly understood by those skilled in the art from the description below.

The inventive concept provides semiconductor packages as follows.

According to an aspect of the inventive concept, there is provided a semiconductor package including a first substrate, a second substrate on the first substrate and electrically connected to the first substrate, a first semiconductor chip on the second substrate, a first underfill material layer between the first semiconductor chip and the second substrate, a second semiconductor chip on the second substrate and spaced apart from the first semiconductor chip in a horizontal direction, a second underfill material layer between the second semiconductor chip and the second substrate, and an outermost layer conformally extending on and at least partially covering the first underfill material layer and the second underfill material layer, wherein the outermost layer at least partially covers a surface of the first underfill material layer at least partially exposed between the second substrate and the first semiconductor chip and at least partially covers a surface of the second underfill material layer at least partially exposed between the second substrate and the second semiconductor chip.

According to another aspect of the inventive concept, there is provided a semiconductor package including a first substrate, a second substrate on the first substrate and electrically connected to the first substrate, a first semiconductor chip on the second substrate, a first underfill material layer between the first semiconductor chip and the second substrate, a second semiconductor chip on the second substrate and spaced apart from the first semiconductor chip in a horizontal direction, a second underfill material layer between the second semiconductor chip and the second substrate, a molding member at least partially surrounding the first semiconductor chip and the second semiconductor chip on an upper surface of the second substrate that is opposite the first substrate, and an outermost layer distinct from the molding member and at least partially covering the molding member and the second substrate, wherein the outermost layer at least partially covers side and upper surfaces of the molding member and a side surface of the second substrate relative to the upper surface of the second substrate.

According to another aspect of the inventive concept, there is provided a semiconductor package including a first substrate, a second substrate on the first substrate and electrically connected to the first substrate, a stiffener on the first substrate and spaced apart from the second substrate in a horizontal direction, a first semiconductor chip on the second substrate, a first underfill material layer between the first semiconductor chip and the second substrate, a second semiconductor chip on the second substrate and spaced apart from the first semiconductor chip in the horizontal direction, a second underfill material layer between the second semiconductor chip and the second substrate, a molding member at least partially surrounding the first semiconductor chip and the second semiconductor chip on an upper surface of the second substrate, and an outermost layer distinct from the molding member and at least partially covering the molding member, the first substrate, and the second substrate, wherein the outermost layer at least partially covers side and upper surfaces of the first molding member, at least partially covers a side surface of the second substrate, and at least partially covers at least a portion of an upper surface of the first substrate, the side surface of the first molding member is substantially coplanar with the side surface of the second substrate, and the upper surface of the first molding member is substantially coplanar with the upper surface of the first semiconductor chip and the upper surface of the second semiconductor chip.

### BRIEF DESCRIPTION OF THE DRAWINGS

Embodiments will be more clearly understood from the following detailed description taken in conjunction with the accompanying drawings in which:

FIG. 1A is a plan view schematically illustrating a semiconductor package according to embodiments;

FIG. 1B is a cross-sectional view of the semiconductor package taken along line X1-X1′ of FIG. 1A;

FIG. 1C is a cross-sectional view schematically illustrating a first semiconductor chip of the semiconductor package of FIG. 1A;

FIG. 1D is a cross-sectional view schematically illustrating an embodiment of a second semiconductor chip of the semiconductor package of FIG. 1A;

FIG. 2 is an enlarged view of portion AA of the outermost layer of the semiconductor package of FIG. 1B;

FIG. 3 is a cross-sectional view schematically illustrating an outermost layer according to an embodiment;

FIG. 4 is a cross-sectional view schematically illustrating an outermost layer according to an embodiment;

FIG. 5 is a cross-sectional view schematically illustrating an outermost layer according to an embodiment;

FIG. 6 is a cross-sectional view schematically illustrating a semiconductor package according to an embodiment;

FIG. 7 is a cross-sectional view schematically illustrating a semiconductor package according to an embodiment;

FIG. 8 is a cross-sectional view schematically illustrating a semiconductor package according to an embodiment;

FIG. 9 is a cross-sectional view schematically illustrating a semiconductor package according to an embodiment; and

FIG. 10 is a cross-sectional view schematically illustrating a semiconductor package according to an embodiment.

### DETAILED DESCRIPTION OF THE EMBODIMENTS

Hereinafter, embodiments are described in detail with reference to the accompanying drawings. The same reference numerals are used for the same components in the drawings, and redundant descriptions thereof are omitted.

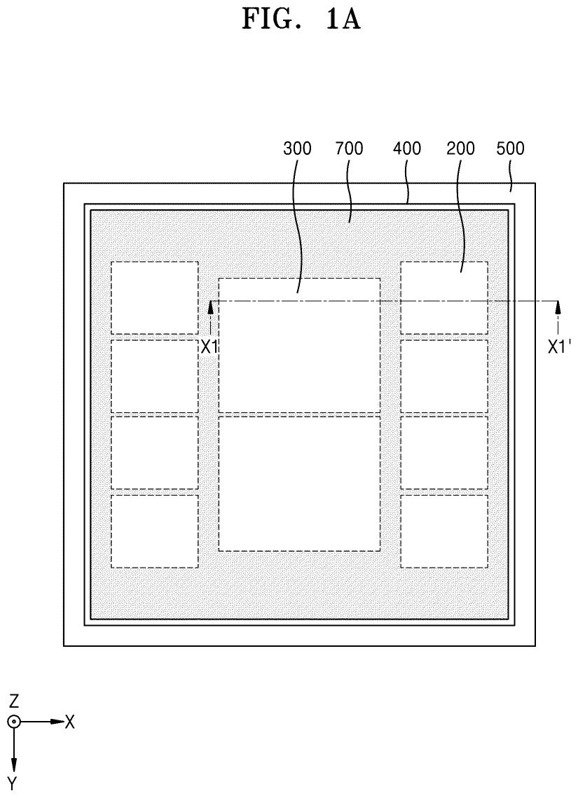

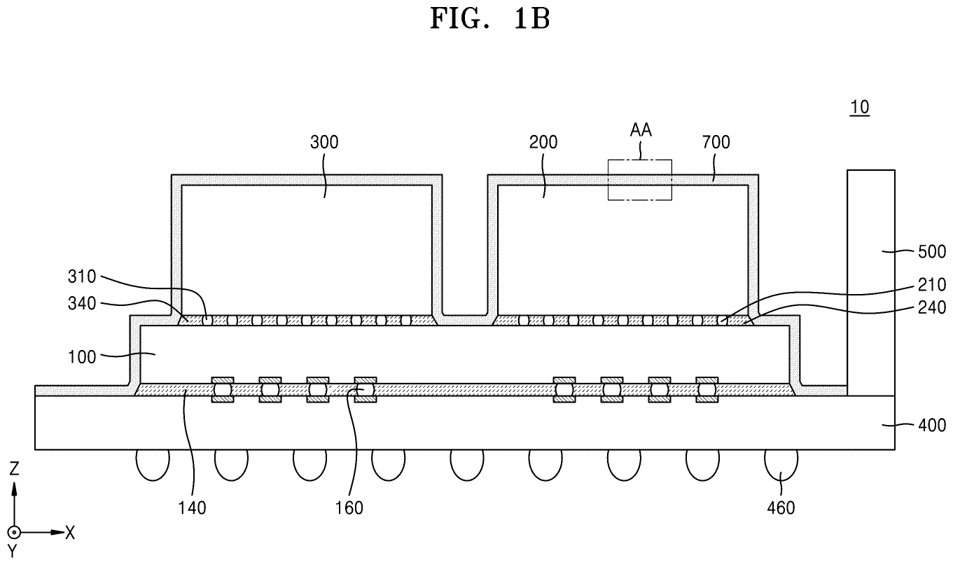

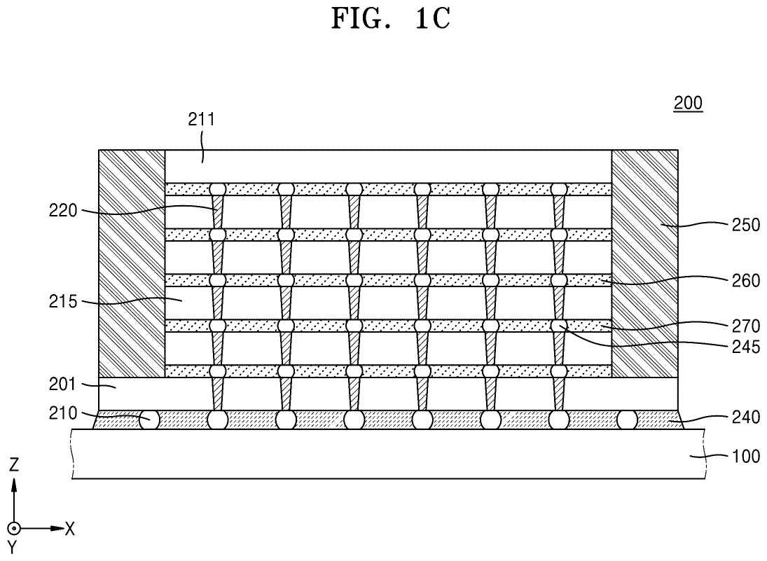

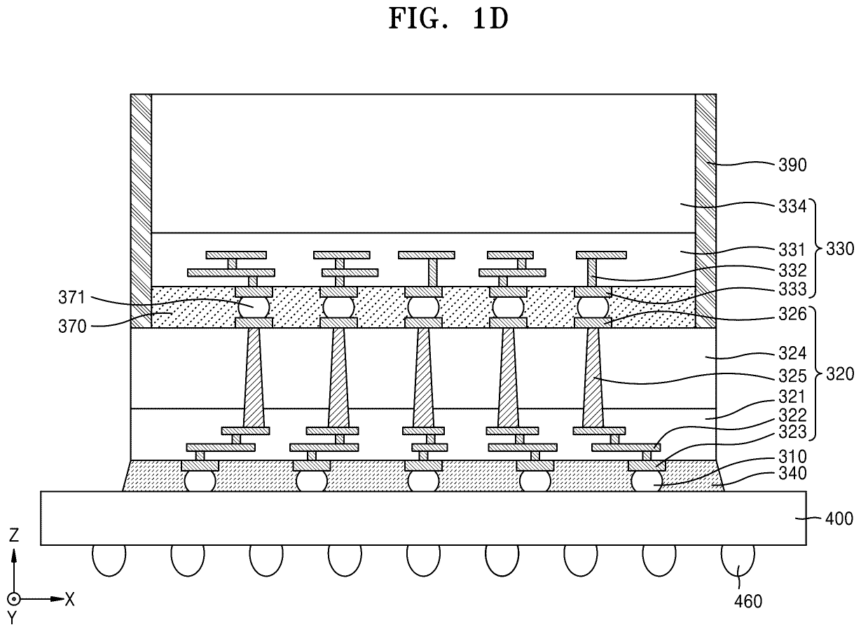

FIG. 1A is a plan view schematically illustrating a semiconductor package 10 according to some embodiments of the present inventive concept. FIG. 1B is a cross-sectional view of the semiconductor package 10 taken along line X1-X1′ of FIG. 1A. FIG. 1C is a cross-sectional view schematically illustrating a first semiconductor chip 200 of the semiconductor package 10 of FIG. 1A. FIG. 1D is a cross-sectional view schematically illustrating an embodiment of a second semiconductor chip 300 of the semiconductor package 10 of FIG. 1A.

Referring to FIGS. 1A-ID, in some embodiments, a first substrate 400 is electrically connected to a second substrate 100 and may be electrically connected to the first semiconductor chip 200 and the second semiconductor chip 300 through the second substrate 100. In some embodiments, the first substrate 400 define a base reference plane. The first substrate 400 may be formed from, for example, a ceramic substrate, a printed circuit board (PCB), or an organic substrate but is not limited thereto. In some embodiments, the first substrate 400 may include an interconnection formed within the first substrate 400 and an insulating layer at least partially surrounding the interconnection. The interconnection may include at least one selected from copper, nickel, stainless steel, and/or beryllium copper, and the insulating layer may include frame retardant 4 (FR-4), tetrafunctional epoxy, polyphenylene ether, epoxy/polyphenylene oxide, bismaleimide triazine (BT), thermount, cyanate ester, polyimide, and/or liquid crystal polymer. In some embodiments, the first substrate 400 may be electrically connected to the second substrate 100 through a first bump 160. In some embodiments, external bonding terminals 460 may be attached to the first substrate.

The first bump 160 may be in physical contact with each of a pad formed on an upper surface of the first substrate 400 and a pad formed on a lower surface of the second substrate 100 to electrically connect the first substrate 400 to the second substrate 100. According to some embodiments, the first bump 160 may include a pillar structure, a ball structure, or a solder layer. In some embodiments, An underfill material layer 140 (also referenced to herein as a third underfill material layer 140) at least partially surrounding the first bump 160 may be disposed between the first substrate 400 and the second substrate 100. According to some embodiments, the third underfill material layer 140 may be formed by any one of a capillary under-fill process, a no-flow under-fill process, a molded under-fill process, and a non-conducted film process. However, the method of forming the third underfill material layer 140 is not limited thereto. According to some embodiments, the third underfill material layer 140 may have a tapered shape having a horizontal width increasing as a vertical level decreases. However, the shape of the third underfill material layer 140 is not limited thereto.

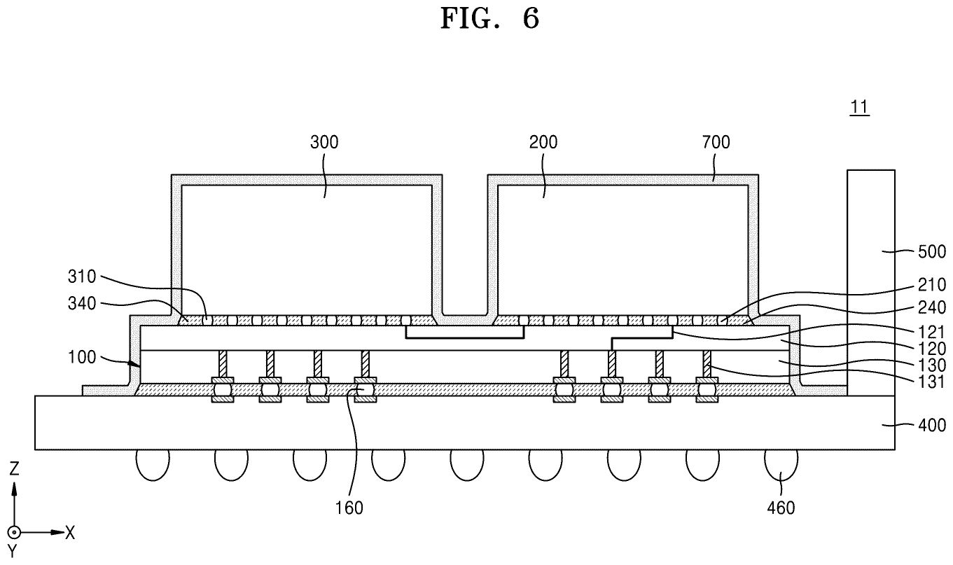

In some embodiments, the second substrate 100 may be a substrate on which the first semiconductor chip 200 and the second semiconductor chip 300 are mounted. However, the inventive concept is not limited thereto, and the second substrate 100 may be a substrate on which only one of the first semiconductor chip 200 and the second semiconductor chip 300 is mounted or a substrate on which three or more types of semiconductor chips are mounted. The second substrate 100 may electrically connect the first semiconductor chip 200 and the second semiconductor chip 300 to each other. In some embodiments, the second substrate 100 may be an interposer substrate electrically connecting the first semiconductor chip 200 to the second semiconductor chip 300. In some embodiments, the second substrate 100 may include a redistribution structure electrically connecting the first semiconductor chip 200 to the second semiconductor chip 300. In some embodiments, the second substrate 100 may include a bridge chip electrically connecting the first semiconductor chip 200 to the second semiconductor chip 300. Embodiments of the second substrate 100 described above are further described in detail below with reference to FIGS. 6, 8, and 9.

In the following drawings, an X-axis direction and a Y-axis direction represent directions parallel to the upper surface of the first substrate 400 (i.e., the first substrate 400 defines a base reference plane), and the X-axis direction may be perpendicular to the Y-axis direction. A Z-axis direction may represent a direction perpendicular to the upper or lower surface of the first substrate 400. In other words, the Z-axis direction may be perpendicular to the X-Y plane.

In addition, in the following drawings, a first horizontal direction, a second horizontal direction, and a vertical direction may be understood as follows. The first horizontal direction may be understood as the X-axis direction, the second horizontal direction may be understood as the Y-axis direction, and the vertical direction may be understood as the Z-axis direction.

The first semiconductor chip 200 may be mounted on an upper surface of the first substrate 400. According to some embodiments, the first semiconductor chip 200 may be provided in a plurality of first semiconductor chips. Some of the plurality of first semiconductor chips 200 may be arranged side-by-side and apart from each other at a certain distance on the upper surface of the first substrate 400 in the second horizontal direction Y. In addition, the others of the plurality of first semiconductor chips 200 may be arranged side-by-side in the second horizontal direction Y and may be apart from each other in the first horizontal direction X with the some first semiconductor chips 200 and the second semiconductor chip 300 therebetween.

The second semiconductor chip 300 may be mounted on the upper surface of the first substrate 400. According to some embodiments, the second semiconductor chip 300 may be provided in a plurality of second semiconductor chips and may be arranged side-by-side and apart from each other at a certain interval in the second horizontal direction Y.

According to some embodiments, the first semiconductor chip 200 may include a memory chip. The memory chip may include, for example, a volatile memory chip, such as dynamic random access memory (DRAM) or static random access memory (SRAM), or a nonvolatile memory chip, such as a phase-change random access memory (PRAM), magnetoresistive random access memory (MRAM), or ferroelectric random access memory (FeRAM), or resistive random access memory (RRAM). However, the inventive concept is not limited thereto, and the semiconductor chip may include a microprocessor, such as a central processing unit (CPU), a graphics processing unit (GPU), or an application processor (AP), or a logic chip, such as an analog element or a digital signal processor.

According to some embodiments, the second semiconductor chip 300 may include a logic chip. The logic chip may include, for example, a microprocessor, such as a CPU, a GPU, or an AP, an analog element, or a digital signal processor.

The types of the first semiconductor chip 200 and the second semiconductor chip 300 are not limited to those described above, and the first semiconductor chip 200 and the second semiconductor chip 300 may include the same type of chips. For example, both the first semiconductor chip 200 and the second semiconductor chip 300 may be memory chips, or both the first semiconductor chip 200 and the second semiconductor chip 300 may be logic chips.

According to some embodiments, the first semiconductor chip 200 may be mounted on the first substrate 400 through a second bump 210 in a flip chip manner. The second bump 210 may include a pillar structure, a ball structure, or a solder layer. A first underfill material layer 240 at least partially surrounding the second bump 210 may be formed between the first semiconductor chip 200 and the second substrate 100. Because the first underfill material layer 240 is substantially the same as or similar to the third underfill material layer 140 described herein, a redundant description thereof is omitted.

According to some embodiments, the first semiconductor chip 200 may include a plurality of semiconductor chips stacked in the vertical direction Z. The semiconductor chips 200 may include high bandwidth memory (HBM) DRAM chips and may be semiconductor chips used in an HBM package. As shown in FIG. 1C, according to some embodiments, the first semiconductor chip 200 may include a base chip 201 and at least one HBM chip 215 stacked in the vertical direction Z on the base chip 201. The base chip 201 may be located at the bottom of the first semiconductor chip 200. Each of the base chip 201 and the HBM chips 215 may include a through-electrode 220 therein. In addition, an uppermost HBM chip 211 among the HBM chips 215 relative to the second substrate 100 may not include the through-electrode 220.

According to some embodiments, the base chip 201 may include logic elements. Accordingly, the base chip 201 may be a logic chip. The base chip 201 may be located below the HBM chips 215 and integrate signals from the HBM chips 215 and transmit the integrated signals externally, and may also transmit signals and power from an external source to the HBM chips 215. Accordingly, the base chip 201 may be referred to as a buffer chip or control chip. The HBM chip 215 may be referred to as a memory chip or core chip.

The HBM chips 215 may be vertically stacked on the base chip 201 through pad-to-pad bonding, bonding using a bonding member, or bonding using an anisotropic conductive film (ACF). Still referring to FIG. 1C, according to some embodiments, the HBM chips 215 may be stacked in a flip chip manner through a fourth bump 245. The fourth bump 245 may include a micro-bump. A fourth underfill material layer 270 may be formed between the base chip 201 and the HBM chip 215 located at the bottom, and between the HBM chips 215. The fourth underfill material layer 270 may fix the fourth bump 245, the base chip 201, and the HBM chips 215.

The through-electrode 220 formed in the base chip 201 and the HBM chips 215 may be electrically connected to the fourth bump 245. The through-electrode 220 may extend in the vertical direction Z. The through-electrode 220 may have a tapered shape having a horizontal width narrowing as the vertical level decreases. According to some embodiments, the through-electrode 220 may include a through silicon via (TSV).

The first semiconductor chip 200 may include a second molding member 250 at least partially surrounding the base chip 201 and the HBM chips 215. The base chip 201 and the HBM chips 215 may be sealed by the second molding member 250. However, in some embodiments, an upper surface of the uppermost HBM chip 211 stacked on the top of the HBM chips 215 relative to the second substrate 100 may not be covered by the second molding member 250. However, in other embodiments, the upper surface of the uppermost HBM chip 211 may be at least partially covered by the second molding member 250.

According to some embodiments, the second molding member 250 may include a thermosetting resin, such as an epoxy resin, a thermoplastic resin, such as polyimide, or a resin including a reinforcing material, such as an inorganic filler including an Ajinomoto build-up film (ABF), FR-4, BT, etc., but is not limited thereto, and the second molding member 250 may be formed from a molding material, such as epoxy molding compound (EMC), or a photosensitive material, such as photoimagable encapsulant (PIE). In some embodiments, a portion of the second molding member 250 may include an insulating material, such as a silicon oxide film, a silicon nitride film, or a silicon oxynitride film.

Referring to FIG. 1D, in some embodiments, the second semiconductor chip 300 may be mounted on the second substrate 100 through a third bump 310 in a flip chip manner. The second semiconductor chip 300 may be arranged on the second substrate 100 to be apart from the first semiconductor chip 200 in the first horizontal direction X. According to some embodiments, the second semiconductor chip 300 may include a logic chip. A second underfill material layer 340 surrounding the third bump 310 may be formed between the second semiconductor chip 300 and the second substrate 100. The second underfill material layer 340 is substantially the same as or similar to the first underfill material layer 240 described herein, and thus, a redundant description thereof is omitted.

As shown in FIG. 1D, according to some embodiments, the second semiconductor chip 300 may include a lower semiconductor chip 320, an upper semiconductor chip 330, an adhesive layer 370, and a molding member 390. The lower semiconductor chip 320 may be disposed on an upper surface of the second substrate 100 (i.e., the second substrate 100 defining a base reference plane). The upper semiconductor chip 330 may be disposed on the upper surface of the lower semiconductor chip 320.

Each of the lower semiconductor chip 320 and the upper semiconductor chip 330 may be a logic chip or a memory chip. For example, in some embodiments, the lower semiconductor chip 320 and the upper semiconductor chip 330 may both be the same type of memory chips, or one of the lower semiconductor chip 320 and the upper semiconductor chip 330 may be a memory chip and the other may be a logic chip. In some embodiments, at least one of the lower semiconductor chip 320 and the upper semiconductor chip 330 may have a chiplet structure including a plurality of chiplets.

In some embodiments, the adhesive layer 370 may be configured to adhere the lower semiconductor chip 320 and the upper semiconductor chip 330 to one another. The adhesive layer 370 may reside between the lower semiconductor chip 320 and the upper semiconductor chip 330. According to some embodiments, the adhesive layer 370 may include a nonconductive film (NCF) or a die attach film (DAF).

In some embodiments, the lower semiconductor chip 320 may include a lower semiconductor substrate 324, a lower semiconductor device layer 321, a first bump pad 323, and a second bump pad 326.

The lower semiconductor substrate 324 may have upper and lower surfaces that are opposite to each other. The upper surface of the lower semiconductor substrate 324 may face the upper semiconductor chip 330 and the lower surface of the lower semiconductor substrate 324 may face the second substrate 100. The upper surface of the lower semiconductor substrate 324 may be referred to as an inactive surface, and the lower surface of the lower semiconductor substrate 324 may be referred to as an active surface.

The lower semiconductor substrate 324 may include silicon (Si), for example, crystalline silicon, polycrystalline silicon, or amorphous silicon. Alternatively, the lower semiconductor substrate 324 may include a semiconductor element, such as germanium (Ge), or a compound semiconductor, such as silicon carbide (SiC), gallium arsenide (GaAs), indium arsenide (InAs), and indium phosphide (InP). Furthermore, the lower semiconductor substrate 324 may have a silicon on insulator (SOI) structure. For example, in some embodiments, the lower semiconductor substrate 324 may include a buried oxide (BOX) layer. The lower semiconductor substrate 324 may include a conductive region, for example, a well doped with an impurity or a structure doped with an impurity. In addition, the lower semiconductor substrate 324 may have various device isolation structures, such as a shallow trench isolation (STI) structure.

In some embodiments, the lower semiconductor device layer 321 may include a first interconnection pattern 322 that is electrically connected to a plurality of semiconductor devices formed in the lower semiconductor substrate 324. The first interconnection pattern 322 may include a metal interconnection layer and a via plug. For example, the first interconnection pattern 322 may have a multi-layer structure in which two or more metal interconnection layers or two or more via plugs are alternately vertically stacked.

According to some embodiments, the lower semiconductor device layer 321 may be formed on the lower surface, which is the active surface, of the lower semiconductor substrate 324. The lower semiconductor device layer 321 may be located below the lower semiconductor substrate 324. The lower semiconductor substrate 324 may be apart from the second substrate 100 in the vertical direction Z with the lower semiconductor device layer 321 therebetween. The lower semiconductor chip 320 may include a through-electrode 325 extending through at least a portion of the lower semiconductor device layer 321 and the lower semiconductor substrate 324.

The first bump pad 323 may be disposed on a lower surface of the lower semiconductor device layer 321 and may be electrically connected to the first interconnection pattern 322 within the lower semiconductor device layer 321. The first bump pad 323 may be electrically connected to the through-electrode 325 through the first interconnection pattern 322.

The through-electrode 325 may extend through the lower semiconductor substrate 324 and a portion of the lower semiconductor device layer 321. The through-electrode 325 may extend in the vertical direction Z from the lower semiconductor device layer 321 toward the upper surface of the lower semiconductor substrate 324 and may be electrically connected to the first interconnection pattern 322 provided in the lower semiconductor device layer 321. Accordingly, the first bump pad 323 may be electrically connected to the through-electrode 325 through the first interconnection pattern 322. The through-electrode 325 may have a tapered shape having a width decreasing or increasing in the horizontal direction as the level in the vertical direction increases. At least a portion of the through-electrode 325 may be pillar-shaped. The through-electrode 325 may be a TSV.

The second bump pad 326 may be formed on the upper surface of the lower semiconductor substrate 324, that is, on the inactive surface of the lower semiconductor substrate 324. The second bump pad 326 may include substantially the same material as that of the first bump pad 323. In addition, although not shown, according to embodiments, a passivation layer may be formed to at least partially surround a portion of a side surface of the second bump pad 326 on the upper surface of the lower semiconductor substrate 324.

The second underfill material layer 340 may reside between the lower semiconductor chip 320 and the second substrate 100. The second underfill material layer 340 may at least partially surround the third bump 310 and reside between the lower semiconductor chip 320 and the second substrate 100. In some embodiments, the second underfill material layer 340 may at least partially cover at least a portion of a side surface of the lower semiconductor chip 320.

The third bump 310 may be disposed to contact the first bump pad 323. The third bump 310 may electrically connect the second semiconductor chip 300 to the second substrate 100. The lower semiconductor chip 320 may receive at least one of a control signal, a power signal, and a ground signal for an operation of the lower semiconductor chip 320 from an external source through the third bump 310, may receive a data signal to be stored in the lower semiconductor chip 320 from an external source, or may provide data stored in the lower semiconductor chip 320 to the outside.

Still referring to FIG. 1D, in some embodiments, the upper semiconductor chip 330 may include an upper semiconductor substrate 334, an upper semiconductor device layer 331, and a third bump pad 333. The upper semiconductor chip 330 may have characteristics that are the same as or similar to those of the lower semiconductor chip 320, and thus, the difference of the upper semiconductor chip 330 from the lower semiconductor chip 320 is mainly described below.

The upper semiconductor substrate 334 may have lower and upper surfaces that are opposite to each other. The lower surface of the upper semiconductor substrate 334 may face the lower semiconductor chip 320, and the upper surface of the upper semiconductor substrate 334 may be opposite to the lower surface of the upper semiconductor substrate 334. The upper surface of the upper semiconductor substrate 334 may be referred to as an inactive surface, and the lower surface of the upper semiconductor substrate 334 may be referred to as an active surface.

The upper semiconductor device layer 331 may include a second interconnection pattern 332 that is electrically connected to a plurality of semiconductor devices formed in the upper semiconductor substrate 334. The second interconnection pattern 332 may include a metal interconnection layer and a via plug. For example, the second interconnection pattern 332 may have a multilayer structure in which two or more metal interconnection layers or two or more via plugs are alternately vertically stacked.

According to some embodiments, the upper semiconductor device layer 331 may be formed on the lower surface, which is the active surface, of the upper semiconductor substrate 334. The upper semiconductor device layer 331 may be located below the upper semiconductor substrate 334. The upper semiconductor substrate 334 may be apart from the lower semiconductor chip 320 in the vertical direction Z with the upper semiconductor device layer 331 therebetween.

The third bump pad 333 may be disposed on the lower surface of the upper semiconductor device layer 331 and may be electrically connected to the second interconnection pattern 332 within the upper semiconductor device layer 331.

In some embodiments, the adhesive layer 370 may reside between the lower semiconductor chip 320 and the upper semiconductor chip 330. The adhesive layer 370 may electrically connect the lower semiconductor chip 320 to the upper semiconductor chip 330 and fix the upper semiconductor chip 330 on the lower semiconductor chip 320.

A fifth bump 371 may be disposed to contact the second bump pad 326 and the third bump pad 333. The fifth bump 371 may electrically connect the lower semiconductor chip 320 to the upper semiconductor chip 330. The upper semiconductor chip 330 may be electrically connected to the lower semiconductor chip 320 through the fifth bump 371 between the lower semiconductor chip 320 and the upper semiconductor chip 330. The upper semiconductor chip 330 may receive at least one of a control signal, a power signal, and a ground signal for an operation of the upper semiconductor chip 330 through the fifth bump 371, may receive a data signal to be stored in the upper semiconductor chip 330, or may provide data stored in the upper semiconductor chip 330 to the outside. When the first semiconductor chip 200 includes HBM chips 215 and the second semiconductor chip 300 includes the upper semiconductor chip 330 and the lower semiconductor chip 320, the semiconductor package 10 may be understood as a 3.5D package.

As shown in FIG. 6, a stiffener 500 may be formed on the upper surface of the first substrate 400 and spaced apart from the second substrate 100 in the first horizontal direction X. The stiffener 500 may have a shape extending in the vertical direction Z. According to some embodiments, the upper surface of the stiffener 500 may reside at a higher vertical plane than the upper surfaces of each of the first semiconductor chip 200 and the second semiconductor chip 300 with the first substrate 400 defining a base reference plane. The stiffener 500 may extend from the upper surface of the first substrate 400 in the vertical direction Z and at least partially surround the first semiconductor chips 200 and the second semiconductor chips 300. The stiffener 500 may include metal, such as steel or copper (Cu).

In some embodiments, an outermost layer 700 may at least partially cover exposed surfaces of the first semiconductor chip 200, the second semiconductor chip 300, and the second substrate 100. In detail, in some embodiments, the outermost layer 700 may at least partially cover the upper and side surfaces of each of the first semiconductor chip 200 and the second semiconductor chip 300. In some embodiments, the outermost layer 700 may at least partially cover the first underfill material layer 240 between the first semiconductor chip 200 and the second substrate 100 and the second underfill material layer 340 between the second semiconductor chip 300 and the second substrate 100. In some embodiments, at least a portion of the surface of the first underfill material layer 240 may be exposed from the second substrate 100 and the second semiconductor chip 300, and a portion of the surface of the second underfill material layer 340 may be exposed from the second substrate 100 and the second semiconductor chip 300. Here, the exposed surface of each of the first underfill material layer 240 and the second underfill material layer 340 may be at least partially covered by the outermost layer 700. According to some embodiments, the surfaces of the first underfill material layer 240 and the second underfill material layer 340 at least partially covered by the outermost layer 700 may be a side surface of the first underfill material layer 240 and a side surface of the second underfill material layer 340.

According to some embodiments, the first underfill material layer 240 and the second underfill material layer 340 may have a horizontal width increasing as the vertical level decreases. Accordingly, the outermost layer 700 at least partially covering the exposed surfaces of the first underfill material layer 240 and the second underfill material layer 340 may be formed to be inclined. That is, the outermost layer 700 at least partially covering the exposed surfaces of the first underfill material layer 240 and the second underfill material layer 340 may be formed to become distant from the center of each of the first underfill material layer 240 and the second underfill material layers 340, as the vertical level decreases. In the same sense, the outermost layer 700 at least partially covering the exposed surfaces of the first underfill material layer 240 and the second underfill material layer 340 may be formed at a certain angle relative to the upper surface of the second substrate 100. The certain angle may be understood as either an acute angle or an obtuse angle.

In some embodiments, the outermost layer 700 may at least partially cover the second substrate 100. In detail, in some embodiments, the outermost layer 700 may at least partially cover the surface of the second substrate 100 exposed from the first underfill material layer 240, the second underfill material layer 340, and the first substrate 400. According to some embodiments, the surface of the second substrate 100 at least partially covered by the outermost layer 700 may be the side surface and a portion of the upper surface of the second substrate 100. The portion of the upper surface of the second substrate 100 may be a portion of the upper surface of the second substrate 100 that does not overlap the first underfill material layer 240 and the second underfill material layer 340 in the vertical direction Z.

According to some embodiments, the outermost layer 700 may at least partially cover the third underfill material layer 140. In detail, in some embodiments, the outermost layer 700 may at least partially cover the surface exposed from the first substrate 400 and the second substrate 100 in the third underfill material layer 140 residing therebetween. According to some embodiments, the surface exposed from the first substrate 400 and the second substrate 100 in the third underfill material layer 140 may be a side surface of the third underfill material layer 140. According to some embodiments, the third underfill material layer 140 may have a shape having a horizontal width increasing as the vertical level decreases. Accordingly, the outermost layer 700 at least partially covering the third underfill material layer 140 may be formed at a certain angle relative to the first substrate 400, and the certain angle may be understood as one of an acute angle and an obtuse angle.

In some embodiments, the outermost layer 700 may cover the entire surface exposed in the vertical direction Z on the upper surface of the first substrate 400. For example, in some embodiments, the outermost layer 700 may cover the entire surface on the upper surface of the first substrate 400 that does not overlap the third underfill material layer 140 and the stiffener 500 in the vertical direction Z. In the same sense, in some embodiments, the outermost layer 700 may cover the entire surface exposed by the third underfill material layer 140 and the stiffener 500 on the upper surface of the first substrate 400. However, in other embodiments, the outermost layer 700 may cover only a portion of the surface exposed by the third underfill material layer 140 and the stiffener 500 on the upper surface of the first substrate 400.

The outermost layer 700 may be formed to have a certain thickness. That is, the outermost layer 700 covering the surface of the second substrate 100, the outermost layer 700 covering the surface of each of the first semiconductor chip 200 and the second semiconductor chip 300, the outermost layer 700 covering the surface of each of the first underfill material layer 240, the second underfill material layer 340, and the third underfill material layer 140, and the outermost layer 700 covering at least a portion of the upper surface of the first substrate 400 may be formed to have substantially the same thickness. That is, the outermost layer 700 may conformally extend on at least a portion of the surface of each of the first semiconductor chip 200 and the second semiconductor chip 300, and in some embodiments, at least a portion of the surfaces of the first and second substrate 100, 400, with a substantially uniform thickness.

The outermost layer 700 may be formed by at least one of a sputtering process, a dipping process, an ink jetting process, a chemical vapor deposition (CVD) process, and a physical vapor deposition (PVD) process.

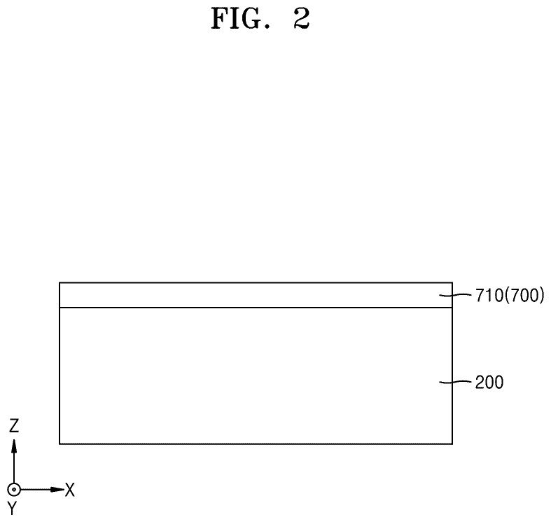

The outermost layer 700 may at least partially cover at least one of the first semiconductor chip 200, the second semiconductor chip 300, the first underfill material layer 240 residing between the first semiconductor chip 200 and the second substrate 100, the second underfill material layer 340 residing between the second semiconductor chip 300 and the second substrate 100, the second substrate 100, the first substrate 400, and the third underfill material layer 140 residing between the first substrate 400 and the second substrate 100. The outermost layer 700 may prevent the element(s) covered by the outermost layer 700 from being oxidized. In some embodiments, the outermost layer 700 may perform an electromagnetic interference (EMI) shielding function. The outermost layer 700 may prevent moisture from penetrating the element(s) covered by the outermost layer 700. When the outermost layer 700 covers the first semiconductor chip 200, the second semiconductor chip 300, the first underfill material layer 240, the second underfill material layer 340, the second substrate 100, the first substrate 400, and the third underfill material layer 140, the first semiconductor chip 200, the second semiconductor chip 300, the first underfill material layer 240, the second underfill material layer 340, the second substrate 100, the first substrate 400, and the third underfill material layer 140 may be prevented from being oxidized. In addition, the outermost layer 700 may prevent moisture from penetrating the first semiconductor chip 200, the second semiconductor chip 300, the first underfill material layer 240, the second underfill material layer 340, the second substrate 100, the first substrate 400, and the third underfill material layer 140. In particular, the outermost layer 700 may effectively prevent the underfill material layers 140, 240, and 340 including an organic material from being oxidized or cracked due to moisture absorption. In addition, in a reliability test of the semiconductor package 10, the components of the semiconductor package 10 may react with oxygen due to a high-temperature environment to cause deterioration of material properties, and the outermost layer 700 may prevent the components of the semiconductor package 10 from reacting with oxygen in the high-temperature environment. The structure and function of the outermost layer 700 are described in detail with reference to FIGS. 2 to 5.

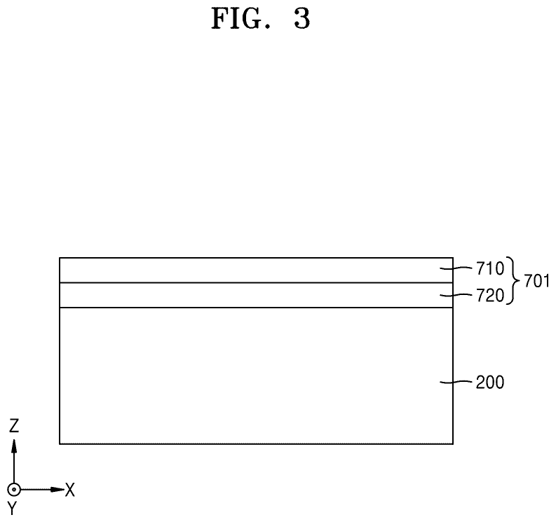

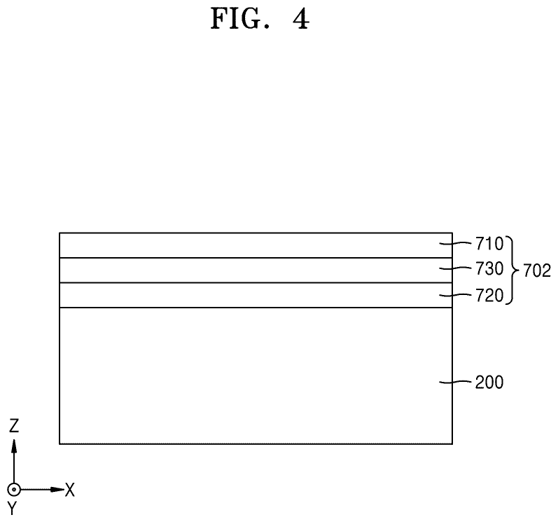

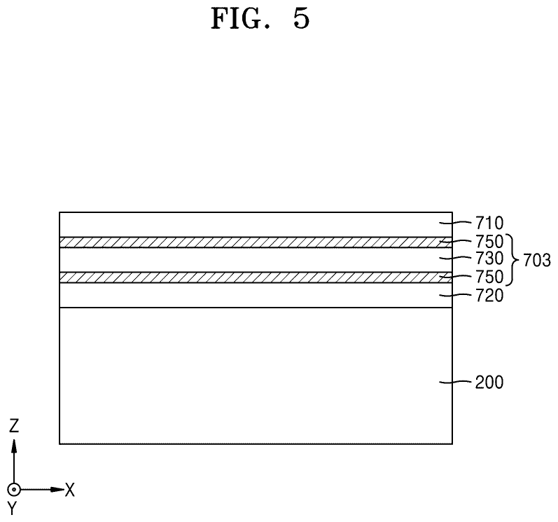

FIG. 2 is an enlarged view of portion AA of the outermost layer 700 in FIG. 1B. FIG. 3 is a cross-sectional view schematically illustrating an outermost layer 701 according to an embodiment. FIG. 4 is a cross-sectional view schematically illustrating an outermost layer 702 according to an embodiment. FIG. 5 is a cross-sectional view schematically illustrating an outermost layer 703 according to an embodiment. In FIGS. 2 to 5, an embodiment in which the outermost layers 700, 701, 702, and 703 cover the first semiconductor chip 200 is shown, but the embodiment is not limited thereto, and the outermost layers 700, 701, 702, and 703 may cover the second semiconductor chip 300, the second substrate 100, the first substrate 400, and the underfill material layers 140, 240, and 340 as described above with reference to FIGS. 1A to IC.

Referring to FIGS. 2 to 5, the outermost layer 700 may at least partially cover the surface of the first semiconductor chip 200. According to some embodiments, as shown in FIG. 2, the outermost layer 700 may include a single layer. The outermost layer 700 may include an oxidation/moisture absorption prevention layer 710. The oxidation/moisture absorption prevention layer 710 may be formed on at least a portion of the surface of the first semiconductor chip 200, may prevent the first semiconductor chip 200 from reacting with external air and being oxidized, and may prevent external moisture from penetrating the first semiconductor chip 200. According to some embodiments, when the outermost layer 700 includes only the oxidation/moisture absorption prevention layer 710, the oxidation/moisture absorption prevention layer 710 may include at least one of titanium dioxide (TiO₂), steel, use, stainless (SUS), chromium (Cr), titanium (Ti), and brass.

According to some embodiments, as shown in FIG. 3, the outermost layer 701 may include two layers. The outermost layer 701 may include an oxidation prevention layer 720 at least partially covering the surface of the first semiconductor chip 200 and an oxidation/moisture absorption prevention layer 710 at least partially covering a surface of the oxidation prevention layer 720. The oxidation prevention layer 720 may be formed from at least one of ortho-substituted phenol, amine, imide, urethane, silicone, a sulfur compound, and a phosphorus compound. The oxidation prevention layer 720 may prevent the first semiconductor chip 200 from being oxidized by reacting with external air. When the outermost layer 701 includes the oxidation prevention layer 720 and the oxidation/moisture absorption prevention layer 710, the first semiconductor chip 200 may be double sealed so that oxidation of the first semiconductor chip 200 and penetration of external moisture into the first semiconductor chip 200 may efficiently be prevented.

The number of layers included in the outermost layers 700, 701, and 702 described above with reference to FIGS. 2 to 4 is not limited to the above, and the outermost layers 700, 701, and 702 may include four or more layers. In addition, the order in which the layers included in the outermost layers 701 and 702 are stacked is also not limited to the order described above.

According to some embodiments, as shown in FIG. 5, the outermost layer 703 may include an adhesive layer 750 formed between layers. In some embodiments, the adhesive layer 750 may reside between the oxidation prevention layer 720 and an EMI shielding layer 730. In some embodiments, the adhesive layer 750 may reside between the EMI shielding layer 730 and the oxidation/moisture absorption prevention layer 710. However, the position of the adhesive layer 750 is not limited to the above, and in the case of the outermost layer 701 illustrated in FIG. 3, the adhesive layer 750 may reside between the oxidation prevention layer 720 and the oxidation prevention/moisture absorption layer 710.

The adhesive layer 750 may be configured to fix layers located above and below (i.e., adjacent to) the adhesive layer 750. According to some embodiments, the adhesive layer 750 may include SUS. In some embodiments, the adhesive layer 750 may be formed through surface modification of layers included in the outermost layer 703. For example, the adhesive layer 750 formed between the oxidation prevention layer 720 and the EMI shielding layer 730 may be formed on the surface of the oxidation prevention layer 720 through at least one of a vacuum (degas) process, a plasma process, an SUS deposition process, and a copper deposition process.

According to some embodiments, the outermost layers 700, 701, 702, and 703 may be configured to form a water-repellent coating on the semiconductor package 10 (see FIG. 1B) when the semiconductor package 10 is liquid-cooled. In addition, the outermost layers 700, 701, 702, and 703 may be configured to provide a path through which heat generated within the semiconductor package 10 is easily discharged externally.

FIG. 6 is a cross-sectional view schematically illustrating a semiconductor package 11 according to an embodiment of the present inventive concept. Hereinafter, any redundant description of the semiconductor package 11 of FIG. 6 with respect to the semiconductor package 10 of FIGS. 1A to IC is omitted and the differences therebetween are mainly described below.

Referring to FIG. 6, according to some embodiments, the semiconductor package 11 may include the first substrate 400, the second substrate 100, the first semiconductor chip 200, the second semiconductor chip 300, the stiffener 500, and the outermost layer 700. The second substrate 100 may include an interposer substrate 130, an interconnection layer 120, and a through-electrode 131. The second substrate 100 may be disposed such that the interposer substrate 130 is positioned to face the first substrate 400. According to some embodiments, the interposer substrate 130 may be formed from silicon. The through-electrode 131 may extend through the interposer substrate 130 in the vertical direction. The through-electrode 131 may be electrically connected to the first bump 160 through a pad formed on a lower surface of the interposer substrate 130. The interconnection layer 120 may include an interconnection pattern 121. The interconnection pattern 121 may electrically connect the first semiconductor chip 200 to the second semiconductor chip 300 or may electrically connect the first semiconductor chip 200 to the through-electrode 131 and the second semiconductor chip 300 to the through-electrode 131.

According to some embodiments, the outermost layer 700 may cover only a portion of the upper surface of the first substrate 400. The outermost layer 700 may cover a region of the upper surface of the first substrate 400 that does not overlap the second substrate 100 and the stiffener 500 in the vertical direction Z but may not entirely cover the non-overlapping region and cover only a portion thereof.

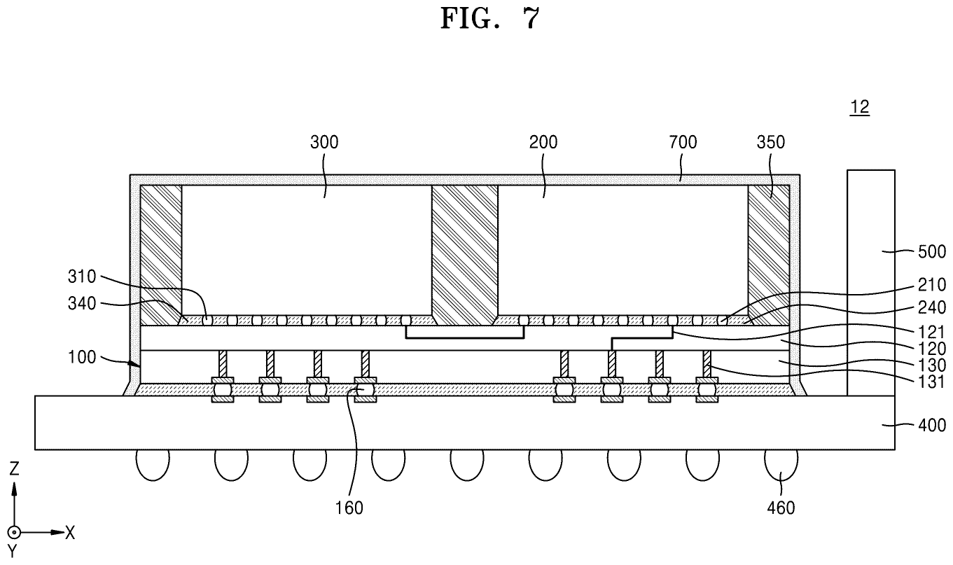

FIG. 7 is a cross-sectional view schematically illustrating a semiconductor package 12 according to an embodiment of the present inventive concept. Hereinafter, any redundant description of the semiconductor package 12 with respect to the semiconductor package 11 described above with reference to FIG. 6 is omitted and the differences therebetween are mainly described below.

Referring to FIG. 7, according to some embodiments, the semiconductor package 12 includes the first substrate 400, the second substrate 100, the first semiconductor chip 200, the second semiconductor chip 300, the stiffener 500, a first molding member 350, and the outermost layer 700.

The first molding member 350 may be formed to at least partially surround the first semiconductor chip 200 and the second semiconductor chip 300. According to some embodiments, the first molding member 350 may be formed to at least partially cover the side surface of each of the first semiconductor chip 200 and the second semiconductor chip 300. Here, the first molding member 350 may not cover the upper surfaces of each of the first semiconductor chip 200 and the second semiconductor chip 300. However, the inventive concept is not limited thereto, and in some embodiments, the first molding member 350 may at least partially cover the upper surface of each of the first semiconductor chip 200 and the second semiconductor chip 300. In some embodiments, the first molding member 350 may at least partially cover the upper surface of the second substrate 100. In some embodiments, the first molding member 350 may at least partially cover the first underfill material layer 240 and the second underfill material layer 340. A side surface of the first molding member 350 may be coplanar with a side surface of the second substrate 100. According to some embodiments, an upper surface of the first molding member 350 may be substantially coplanar with the upper surface of the first semiconductor chip 200 and the upper surface of the second semiconductor chip 300.

According to some embodiments, the first molding member 350 may include a thermosetting resin, such as an epoxy resin, a thermoplastic resin, such as polyimide, or a resin including a reinforcing material, such as an inorganic filler including ABF, FR-4, BT, etc., but is not limited thereto, and the first molding member 350 may be formed from a molding material, such as EMC, or a photosensitive material, such as PIE. In some embodiments, a portion of the first molding member 350 may include an insulating material, such as a silicon oxide film, a silicon nitride film, or a silicon oxynitride film.

In some embodiments, the outermost layer 700 may be formed to at least partially cover the first molding member 350. According to some embodiments, the outermost layer 700 may at least partially cover the side and upper surfaces of the first molding member 350. According to some embodiments, the outermost layer 700 may at least partially cover an exposed surface of the second substrate 100. In detail, in some embodiments, the outermost layer 700 may at least partially cover the surface of the second substrate 100 exposed from the molding member 350, the first underfill material layer 240 residing between the first semiconductor chip 200 and second substrate 100, the second underfill material layer 340 residing between the second semiconductor chip 300 and the second substrate 100, and the third underfill material layer 140 residing between the first substrate 400 and the second substrate 100. In some embodiments, the outermost layer 700 may at least partially cover the side surface of the second substrate 100. According to some embodiments, the outermost layer 700 may at least partially cover the exposed surface of the third underfill material layer 140. In detail, in some embodiments, the outermost layer 700 may at least partially cover the second substrate 100 and the surface exposed from the first substrate 400 in the third underfill material layer 140.

Because the outermost layer 700 at least partially covers the surface of the molding member 350, oxidation of the first molding member 350 or penetration of external moisture into the first molding member 350 may be prevented. Accordingly, the reliability of the semiconductor package 12 may be improved.

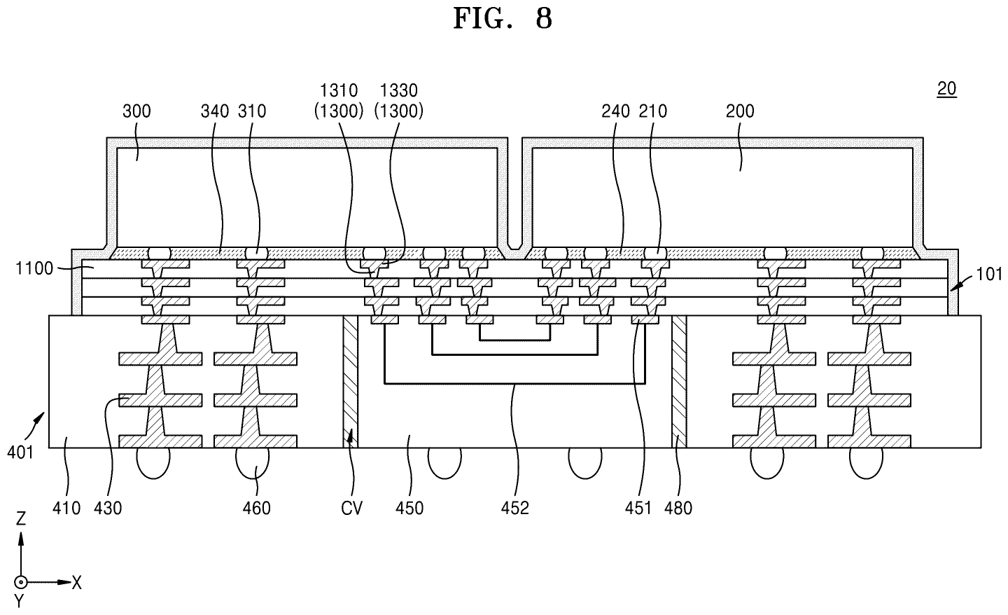

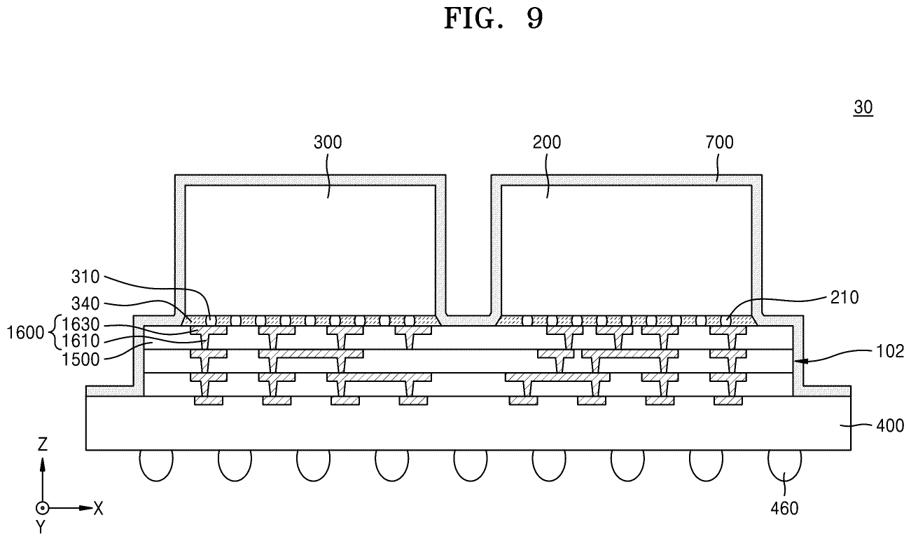

Referring to FIG. 7, an embodiment of the present inventive concept in which the second substrate 100 includes the interposer substrate 130, the interconnection layer 120, and the through-electrode 131 is illustrated, but the inventive concept is not limited thereto. As shown in FIGS. 8 and 9, in some embodiments, the second substrate 100 may include redistribution insulating layers 1100 and 1500 and redistribution patterns 1300 and 1600 and the first molding member 350 may be formed to at least partially cover the upper surface of the second substrate 100.

FIG. 8 is a cross-sectional view schematically illustrating a semiconductor package 20 according to an embodiment of the present inventive concept. Hereinafter, any redundant description of the semiconductor package 20 with respect to the semiconductor package 10 described herein with reference to FIGS. 1A to IC is omitted and the differences therebetween are mainly described below.

Referring to FIG. 8, in some embodiments, the semiconductor package 20 may include a first substrate 401, a second substrate 101, the first semiconductor chip 200, the first underfill material layer 240 residing between the first semiconductor chip 200 and the second substrate 101, the second semiconductor chip 300, the second underfill material layer 340 residing between the second semiconductor chip 300 and the second substrate 101, and the outermost layer 700.

In some embodiments, the first substrate 401 may include a body 410 and a cavity CV extending through the body 410 in the vertical direction Z. An interconnection pattern 430 may be formed within the body 410. A bridge chip 450 may be provided within the cavity CV. An adhesive portion 480 may fix the bridge chip 450 provided within the cavity CV. The adhesive portion 480 may reside between the bridge chip 450 and the body 410.

In some embodiments, the second substrate 101 may include the redistribution insulating layer 1100 and the redistribution pattern 1300. The redistribution pattern 1300 may include a redistribution via pattern 1310 and a redistribution line pattern 1330. The redistribution insulating layers 1100 may be stacked on each other to be provided in the vertical direction Z. The redistribution insulating layer 1100 may be formed from, for example, photo imageable dielectric (PID) or photosensitive polyimide (PSPI). The redistribution pattern 1300 may be provided within the redistribution insulating layer 1100. The redistribution pattern 1300 may be formed to extend through the redistribution insulating layers 1100 from the upper surface of the second substrate 101 to the lower surface of the second substrate 101. Accordingly, the redistribution pattern 1300 may serve as an electrical connection path extending through the upper and lower surfaces of the second substrate 101. That is, the redistribution pattern 1300 may electrically connect each of the first semiconductor chip 200 and the second semiconductor chip 300 to the interconnection pattern 430 of the first substrate 401. In addition, the redistribution pattern 1300 may electrically connect each of the first semiconductor chip 200 and the second semiconductor chip 300 to the bridge chip 450.

The redistribution pattern 1300 may include a metal, for example, copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), etc., or alloys thereof but is not limited thereto. In some embodiments, the redistribution pattern 1300 may be formed by stacking a metal or metal alloy on a seed layer including copper, titanium, titanium nitride, or titanium tungsten.

The redistribution pattern 1300 may include the redistribution line pattern 1330 and the redistribution via pattern 1310. The redistribution pattern 1300 may have a multilayer structure in which the redistribution line patterns 1330 and the redistribution via patterns 1310 are alternately vertically stacked.

The redistribution line pattern 1330 may have a shape extending in the horizontal direction along at least one of upper and lower surfaces of each of the redistribution insulating layers 1100. The redistribution via pattern 1310 may have a shape extending through the redistribution insulating layer 1100 in the vertical direction Z. The redistribution via pattern 1310 may electrically connect the upper redistribution line patterns 533 located at different planes in the vertical direction Z. In some embodiments, at least some of the redistribution line patterns 1330 may be formed together with some of the redistribution via patterns 1310 to form a single body.

Still referring to FIG. 8, in some embodiments, the bridge chip 450 may include a bridge circuit 452 and a bridge pad 451. The bridge chip 450 may connect the first semiconductor chip 200 to the second semiconductor chip 300. The bridge circuit 452 may electrically connect the redistribution pattern 1300 electrically connected to the first semiconductor chip 200 to the redistribution pattern 1300 electrically connected to the second semiconductor chip 300. The bridge pad 451 may be formed on an upper surface of the bridge chip 450 and may be electrically connected to the redistribution pattern 1300 and the bridge circuit 452.

In some embodiments, the outermost layer 700 may at least partially cover at least one of the first semiconductor chip 200, the second semiconductor chip 300, and the second substrate 101. In some embodiments, the first semiconductor chip 200 and the second semiconductor chip 300 may be at least partially covered by a first molding member (not shown), and in this case, the outermost layer 700 may at least partially cover upper and side surfaces of the first molding member and may at least partially cover a side surface of the second substrate 101. In some embodiments, the outermost layer 700 may cover at least a portion of the upper surface of the first substrate 401.

FIG. 9 is a cross-sectional view schematically illustrating a semiconductor package 30 according to an embodiment of the present inventive concept. Hereinafter, any redundant description of the semiconductor package 30 with respect to the semiconductor package 10 described herein with reference to FIGS. 1A to IC is omitted and the differences therebetween are mainly described below.

Referring to FIG. 9, in some embodiments, the semiconductor package 30 may include the first substrate 400, a second substrate 102, the first semiconductor chip 200, the first underfill material layer 240 residing between the first semiconductor chip 200 and the second substrate 102, the second semiconductor chip 300, the second underfill material layer 340 residing between the second semiconductor chip 300 and the second substrate 102, and the outermost layer 700.

The second substrate 102 may be electrically connected to the first substrate 400. In some embodiments, an underfill material layer may not be formed between the second substrate 102 and the first substrate 400. The second substrate 102 may include a redistribution insulating layer 1500 and a redistribution pattern 1600. The redistribution pattern 1600 may include a redistribution line pattern 1630 and a redistribution via pattern 1610. The redistribution insulating layers 1500 may be stacked on each other to be provided in the vertical direction Z, and the redistribution pattern 1600 may be formed within the redistribution insulating layer 1500. The redistribution pattern 1600 may electrically connect the first semiconductor chip 200 to the second semiconductor chip 300. The redistribution pattern 1600 may electrically connect the first semiconductor chip 200 to the first substrate 400 and the second semiconductor chip 300 to the first substrate 400.

In some embodiments, the outermost layer 700 may at least partially cover at least one of the first semiconductor chip 200, the second semiconductor chip 300, the first underfill material layer 240, the second underfill material layer 340, the second substrate 102, and the first substrate 400. In some embodiments, the first semiconductor chip 200 and the second semiconductor chip 300 may be at least partially covered by a first molding member (not shown), and in this case, the outermost layer 700 may at least partially cover upper and side surfaces of the first molding member and may at least partially cover the side surface of the second substrate 102. In some embodiments, the outermost layer 700 may cover at least a portion of the upper surface of the first substrate 400.

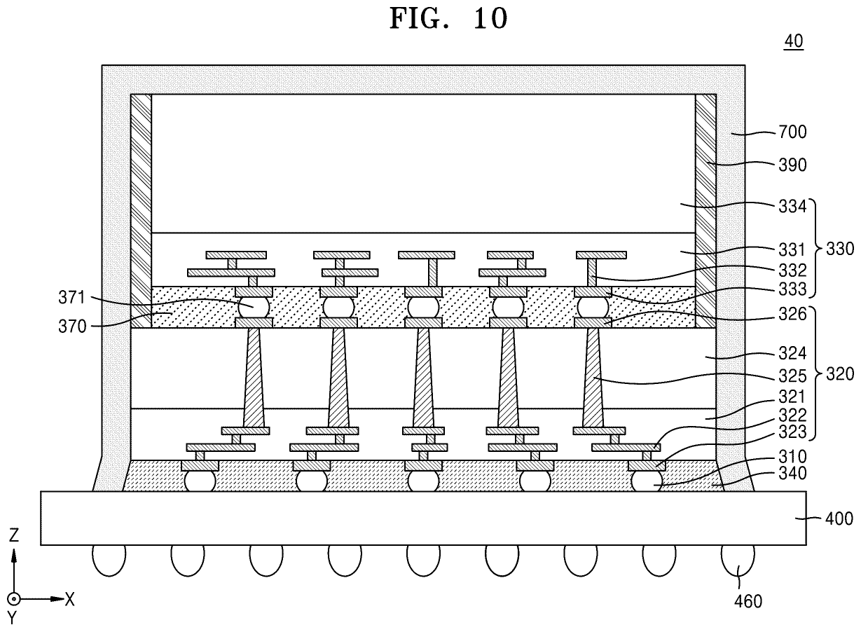

FIG. 10 is a cross-sectional view schematically illustrating a semiconductor package 40 according to an embodiment of the present inventive concept. Hereinafter, any redundant description of the semiconductor package 40 with respect to the semiconductor package 10 described herein with reference to FIGS. 1A to IC is omitted and the differences therebetween are mainly described below.

Referring to FIG. 10, in some embodiments, the semiconductor package 40 may include the first substrate 400, an underfill material layer 340, a bump 310, an upper semiconductor chip 330, a lower semiconductor chip 320, a molding member 390, and the outermost layer 700. The lower semiconductor chip 320 may be mounted on the first substrate 400 through the bump 310 and may be fixed on the first substrate 400 through the underfill material layer 340. The upper semiconductor chip 330 may be vertically stacked on the lower semiconductor chip 320, and the molding member 390 may be formed to at least partially surround the upper semiconductor chip 330. According to some embodiments, the molding member 390 may at least partially cover side and upper surfaces of the upper semiconductor chip 330. In some embodiments, the molding member 390 may at least partially cover only the side surface of the upper semiconductor chip 330. In some embodiments, the molding member 390 may be omitted.

According to some embodiments, the outermost layer 700 may be formed to at least partially surround the molding member 390, the lower semiconductor chip 320, and the underfill material layer 340. In some embodiments, the upper surface of the molding member 390 may be coplanar with the upper surface of the upper semiconductor chip 330, and in this case, the outermost layer 700 may at least partially cover the upper surface of the upper semiconductor chip 330.

In some embodiments, the outermost layer 700 may at least partially cover the upper surface of the first substrate 400. In some embodiments, the outermost layer 700 may cover only a portion of the upper surface of the first substrate 400. However, the inventive concept is not limited thereto, and the outermost layer 700 may cover the entire upper surface of the first substrate 400.

As used herein, an element or region that is “covering” or “surrounding” or “filling” another element or region may completely or partially cover or surround or fill the other element or region.

The term “exposed” (or “expose,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device.

Although terms (e.g., first, second or third) may be used herein to describe various elements, these elements should not be limited by these terms. These terms are only used to distinguish one element from another. For example, a first element may be referred to as a second element, and, similarly a second element may be referred to as a first element without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

It will be understood that when an element is referred to as being “on”, “attached” to, “connected” to, “coupled” with, “contacting”, etc., another element, it can be directly on, attached to, connected to, coupled with or contacting the other element or intervening elements may also be present. In contrast, when an element is referred to as being, for example, “directly on”, “directly attached” to, “directly connected” to, “directly coupled” with or “directly contacting” another element, there are no intervening elements present. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper”, “lateral”, “left”, “right” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is inverted, elements described as “under” or “beneath” other elements or features would then be oriented “over” the other elements or features. The device may be otherwise oriented (rotated 90 degrees or at other orientations) and the descriptors of relative spatial relationships used herein interpreted accordingly.

While the inventive concept has been particularly shown and described with reference to embodiments thereof, it will be understood that various changes in form and details may be made therein without departing from the spirit and scope of the following claims. The above-disclosed subject matter is to be considered illustrative, and not restrictive, and the appended claims are intended to cover all such modifications, enhancements, and other embodiments, which fall within the scope of the present inventive concept. Thus, to the maximum extent allowed by law, the scope is to be determined by the broadest permissible interpretation of the following claims and their equivalents, and shall not be restricted or limited by the foregoing detailed description.

What is claimed is:

1. A semiconductor package comprising:
a first substrate;
a second substrate on the first substrate and electrically connected to the first substrate;
a first semiconductor chip on the second substrate;
a first underfill material layer between the first semiconductor chip and the second substrate;
a second semiconductor chip on the second substrate and spaced apart from the first semiconductor chip in a horizontal direction;
a second underfill material layer between the second semiconductor chip and the second substrate; and
an outermost layer conformally extending on and at least partially covering the first underfill material layer and the second underfill material layer,
wherein the outermost layer at least partially covers a surface of the first underfill material layer at least partially exposed between the second substrate and the first semiconductor chip and at least partially covers a surface of the second underfill material layer at least partially exposed between the second substrate and the second semiconductor chip.

2. The semiconductor package of claim 1, wherein the outermost layer at least partially covers an upper surface and a side surface of each of the first semiconductor chip and the second semiconductor chip relative to an upper surface of the first substrate.

3. The semiconductor package of claim 2, wherein the outermost layer covers an entire surface exposed upwardly in a vertical direction from the upper surface of the first substrate.

4. The semiconductor package of claim 1, wherein
the outermost layer comprises an oxidation/moisture absorption prevention layer, and
the oxidation/moisture absorption prevention layer comprises a titanium dioxide.

5. The semiconductor package of claim 1, wherein the outermost layer comprises an oxidation prevention layer at least partially covering the first underfill material layer and the second underfill material layer and an oxidation/moisture absorption prevention layer at least partially covering the oxidation prevention layer.

6. The semiconductor package of claim 5, further comprising an adhesive layer between the oxidation prevention layer and the oxidation/moisture absorption prevention layer.

7. The semiconductor package of claim 1, wherein the outermost layer comprises an oxidation prevention layer at least partially covering each of the first and second underfill material layers, an electromagnetic interference (EMI) shielding layer at least partially covering the oxidation prevention layer, and an oxidation/moisture absorption prevention layer at least partially covering the EMI shielding layer.

8. The semiconductor package of claim 1, wherein the second substrate comprises an interposer substrate, an interconnection layer on an upper surface of the interposer substrate, and a through-electrode extending through the interposer substrate in a vertical direction in which the second substrate is stacked on the first substrate.

9. The semiconductor package of claim 1, wherein
the first substrate comprises a cavity therein, the cavity is provided with a bridge chip, and
the second substrate comprises a redistribution insulating layer and a redistribution pattern within the redistribution insulating layer.

10. The semiconductor package of claim 1, wherein the second substrate comprises a redistribution insulating layer and a redistribution pattern within the redistribution insulating layer.

11. A semiconductor package comprising:
a first substrate;
a second substrate on the first substrate and electrically connected to the first substrate;
a first semiconductor chip on the second substrate;
a first underfill material layer between the first semiconductor chip and the second substrate;
a second semiconductor chip on the second substrate and apart from the first semiconductor chip in a horizontal direction;
a second underfill material layer between the second semiconductor chip and the second substrate;
a molding member at least partially surrounding the first semiconductor chip and the second semiconductor chip on an upper surface of the second substrate that is opposite the first substrate; and
an outermost layer distinct from the molding member and at least partially covering the molding member and the second substrate,
wherein the outermost layer at least partially covers side and upper surfaces of the molding member and a side surface of the second substrate relative to the upper surface of the second substrate.

12. The semiconductor package of claim 11, wherein the outermost layer covers an entire surface exposed vertically upward from the upper surface of the second substrate.

13. The semiconductor package of claim 11, wherein
the outermost layer comprises an oxidation/moisture absorption prevention layer, and
the oxidation/moisture absorption prevention layer comprises a titanium dioxide.

14. The semiconductor package of claim 11, wherein the outermost layer comprises an oxidation prevention layer at least partially covering the molding member and an oxidation/moisture absorption prevention layer at least partially covering the oxidation prevention layer.

15. The semiconductor package of claim 11, wherein the outermost layer comprises an oxidation prevention layer at least partially covering the molding member, an electromagnetic interference (EMI) shielding layer at least partially covering the oxidation prevention layer, and an oxidation/moisture absorption prevention layer at least partially covering the EMI shielding layer.

16. The semiconductor package of claim 15, wherein a first adhesive layer is between the oxidation prevention layer and the EMI shielding layer and a second adhesive layer is between the EMI shielding layer and the oxidation/moisture absorption prevention layer.

17. The semiconductor package of claim 11, wherein the second substrate comprises an interposer substrate, an interconnection layer on an upper surface of the interposer substrate, and a through-electrode extending through the interposer substrate in a vertical direction in which the second substrate is stacked on the first substrate.

18. A semiconductor package comprising:
a first substrate;
a second substrate on the first substrate and electrically connected to the first substrate;
a stiffener on the first substrate and spaced apart from the second substrate in a horizontal direction;
a first semiconductor chip on the second substrate;
a first underfill material layer between the first semiconductor chip and the second substrate;
a second semiconductor chip on the second substrate and spaced apart from the first semiconductor chip in the horizontal direction;
a second underfill material layer between the second semiconductor chip and the second substrate;
a molding member at least partially surrounding the first semiconductor chip and the second semiconductor chip on an upper surface of the second substrate; and
an outermost layer distinct from the molding member and at least partially covering the molding member, the first substrate, and the second substrate,
wherein the outermost layer at least partially covers side and upper surfaces of the molding member, at least partially covers a side surface of the second substrate, and at least partially covers at least a portion of an upper surface of the first substrate,
wherein the side surface of the molding member is substantially coplanar with the side surface of the second substrate, and
wherein the upper surface of the molding member is substantially coplanar with the upper surface of the first semiconductor chip and the upper surface of the second semiconductor chip.

19. The semiconductor package of claim 18, wherein the second substrate comprises a redistribution insulating layer and a redistribution pattern within the redistribution insulating layer.

20. The semiconductor package of claim 18, wherein
the first substrate comprises a cavity therein, the cavity is provided with a bridge chip, and
the second substrate comprises a redistribution insulating layer and a redistribution pattern within the redistribution insulating layer.
